(19) United States
(12) Patent Application Publication
(10) Pub. No.: US 2008/0182369 A1
(43) Pub. Date: Jul. 31, 2008

(54) T-gate forming method and metamorphic high electron mobility transistor fabricating method using the same

(75) Inventors: Yoon-Ha Jeong, Kyungsangbuk-do (KR); Kang-Sung Lee, Kyungsangbuk-do (KR); Young-Su Kim, Kyungsangbuk-do (KR); Yun-Ki Hong, Kyungsangbuk-do (KR)

Correspondence Address: BACON & THOMAS, PLLC, 625 SLATERS LANE, FOURTH FLOOR, ALEXANDRIA, VA, 22314, US

(73) Assignee: POSTECH ACADEMY-INDUSTRY FOUNDATION, Kyungsangbuk-do (KR)

(21) Appl. No.: 11/896,660

(22) Filed: Sep. 5, 2007

(30) Foreign Application Priority Data
Jan. 30, 2007 (KR) 10-2007-0009217

(51) Int. Cl. H01L 21/338

(52) U.S. Cl. 438/172; 257/E21.45

(57) ABSTRACT

A method for forming a T-gate of a metamorphic high electron mobility transistor is provided. The method includes sequentially laminating a plurality of resist films on a substrate; forming a T-shaped pattern in the laminated resist films using electron beam lithography; forming a gate metal layer on the substrate where the T-shaped pattern has been formed; attaching an adhesion member to the gate metal layer formed on a top surface of the laminated resist films and detaching the adhesion member to thereby remove the gate metal layer; and removing the laminated resist films.

### FIELD OF THE INVENTION

The present invention relates to a method for fabricating a metamorphic high electron mobility transistor (HEMT) that is based on a compound semiconductor; and, more particularly, it relates to a method for forming a stable T-gate on a substrate and optimizing an epitaxial structure to reduce parasitic resistance of a device.

### BACKGROUND OF THE INVENTION

As communications technology has been developing around the world, communications devices applied to a higher frequency region of 2 GHz or more have been requiring higher electron mobility than the conventional devices. Therefore, compound semiconductors having high electron mobility such as gallium arsenide (GaAs), indium phosphide (InP) or the like are more widely used than silicon, which is typically used for more conventional devices. In a case where a field effect transistor is manufactured based on the compounds, the device characteristics thereof at an ultra-high frequency region, e.g., at a millimeter-wave band, highly depend on the gate characteristics such as a gate length and a gate resistance. That is, as the gate length of the ultra-high frequency device becomes shorter, the transconductance increases while the gate-source capacitance decreases. Thus, if the gate length is reduced, the ultra-high frequency characteristics, e.g., a maximum oscillation frequency fₘₐₓ, a current gain cut-off frequency f_{T} or the like are all improved. However, the shorter the gate length is, the smaller the gate cross-sectional area becomes and the larger the resistance of a gate conducting wire results, which causes reduction of the device gain at a high frequency region, and particularly, reduction of the current gain.

In order to solve a trade-off problem between the gate length and the gate resistance, a T-gate structure, where a length of a gate electrode in contact with a schottky layer is short and the entire cross-sectional area of the gate is large, has been used.

Further, in a case where an ultra-high frequency device is manufactured by adopting such a T-gate structure, it is important that a T-gate is stably formed on a substrate, particularly when a gate length is several tens of nanometers or less in length. That is, if the gate length is reduced, there is a chance that a gate can tip over due to physical impact that can be caused in a metal removal process, thereby deteriorating the performance of the device.

FIGS. 1A to 1E illustrate cross sectional views sequentially showing a process of forming a T-gate according to a conventional method and a problem caused thereby.

According to the conventional method for forming a T-gate, a multilayer resist structure is formed on a substrate 101 by laminating a plurality of resist films having different sensitivity to the electron beam. For example, as shown in FIG. 1A, a multilayer resist structure 102 is formed of three layers using polymethyl methacrylate (PMMA), polymethyl methacrylate-methacrylic acid (PMMA-MAA) or the like. Next, a T-shaped pattern is formed by a lithography process using the electron beam, and then, a T-shaped resist structure shown in FIG. 1B is formed through developing and cleaning processes. Further, a gate shown in FIG. 1C is formed by depositing a gate metal 103, which is formed, for example, by sequentially laminating titanium, platinum and gold (hereinafter, referred to as a “titanium/platinum/gold”) from the bottom. After that, as shown in FIG. 1D, the T-gate is formed by removing both the resist films and the metal layer formed thereon using a solvent 104 (hereinafter, referred to as a “lift-off method”).

However, in a case where the conventional lift-off method is used, the resist films are dissolved in the solvent 104 as shown in FIG. 1D. Therefore, while remaining metal is freely moving, it is possible that a physical impact on the minute gate can result making the gate fall down, as shown in FIG. 1E. FIG. 2 is a photograph showing a cross section of a 35 nm T-gate manufactured by the conventional metal removal process. As shown in FIG. 2, the 35 nm T-gate is not erect on the substrate and falls to one side after the metal deposition and removal processes.

On the other hand, for most cases, although the gate length could be successfully reduced, unless parasitic resistance due to the epitaxial structure of the device is reduced, devices with a good current gain cut-off frequency will have a poor maximum oscillation frequency and devices having a good maximum oscillation frequency will have a poor current gain cut-off frequency. However, both the current gain cut-off frequency and the maximum oscillation frequency need to be good in order to fabricate a circuit operated at a high frequency. Accordingly, to reduce the parasitic resistance for the excellent current gain cut-off frequency and maximum oscillation frequency, it is necessary to optimize the epitaxial structure of the device.

### SUMMARY OF THE INVENTION

It is, therefore, an object of the present invention to provide a method for forming a stable T-gate by reducing physical impact on a minute gate during a metal removal process.

Another object of the present invention is to provide a method for manufacturing a metamorphic high electron mobility transistor with high performance by using an epitaxial structure capable of reducing parasitic resistance of a device.

In accordance with an aspect of the present invention, there is provided a method for forming a T-gate of a metamorphic high electron mobility transistor, the method including:

sequentially laminating a plurality of resist films on a substrate;

forming a T-shaped pattern in the laminated resist films using electron beam lithography;

forming a gate metal layer on the substrate where the T-shaped pattern has been formed;

attaching an adhesion member to the gate metal layer formed on a top surface of the laminated resist films and detaching the adhesion member to thereby remove the gate metal layer; and

removing the laminated resist films.

In accordance with another aspect embodiment of the present invention, there is provided a method for forming a metamorphic high electron mobility transistor, the method including:

sequentially laminating a metamorphic buffer layer, an undoped buffer layer, an undoped channel layer, an undoped spacer layer, a delta doping layer, a schottky barrier layer, an etching protective layer and a doped cap layer on a substrate;

forming an ohmic metal layer on the cap layer to thereby form a source and a drain electrode;

sequentially laminating a plurality of resist films on the cap layer on which the source and the drain electrode have been formed;

forming a T-shaped pattern in the laminated resist films using electron beam lithography;

performing a gate recess process for wet etching the cap layer and the etching protective layer using the T-shaped pattern as a mask;

forming a gate metal layer on the substrate after completing the gate recess process;

attaching an adhesion member to the gate metal layer formed on a top surface of the laminated resist films and detaching the adhesion member to thereby remove the gate metal layer; and

removing the laminated resist films.

In accordance with the present invention, the minute gate can be stably formed by the metal removal method using the adhesion member. Further, it is possible to form the high electron mobility transistor capable of performing high speed operation by employing the epitaxial structure having the highly doped indium phosphide etching protective layer to reduce a parasitic resistance component.

### BRIEF DESCRIPTION OF THE DRAWINGS

The above and other objects and features of the present invention will become apparent from the following description of embodiments given in conjunction with the accompanying drawings, in which:

FIGS. 1A to 1E illustrate cross sectional views sequentially showing a process of manufacturing a minute T-gate according to a conventional metal removal process and a problem that arises therefrom;

FIG. 2 is a photograph showing a cross section of a 35 nm T-gate manufactured by the conventional metal removal process;

FIGS. 3A to 3F illustrate cross sectional views sequentially showing a process of forming a T-gate in accordance with the present invention;

FIGS. 4A to 4C are photographs, which are captured by an electron microscope, sequentially showing cross sections of a 35 nm T-gate manufactured by a metal removal method using an adhesion tape in accordance with an embodiment of the present invention;

FIGS. 5A to 5F show cross sectional views sequentially showing a process of forming a T-gate of a metamorphic high electron mobility transistor using a highly doped indium phosphide etching protective layer in accordance with the present invention;

FIGS. 6A and 6B show graphs illustrating measured results of DC current and voltage characteristics of the 35 nm T-gate metamorphic high electron mobility transistor in accordance with embodiment of the present invention; and

FIG. 7 is a graph showing measured results of ultra-high frequency characteristics of the 35 nm T-gate metamorphic high electron mobility transistor in accordance with the embodiment of the present invention.

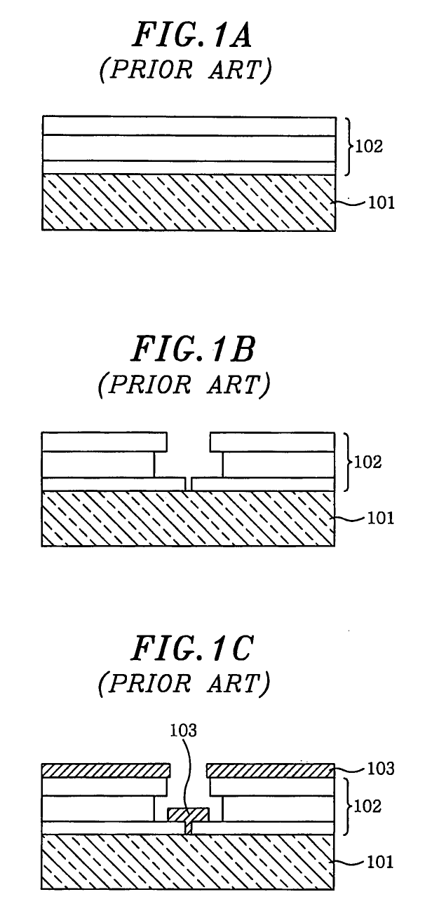

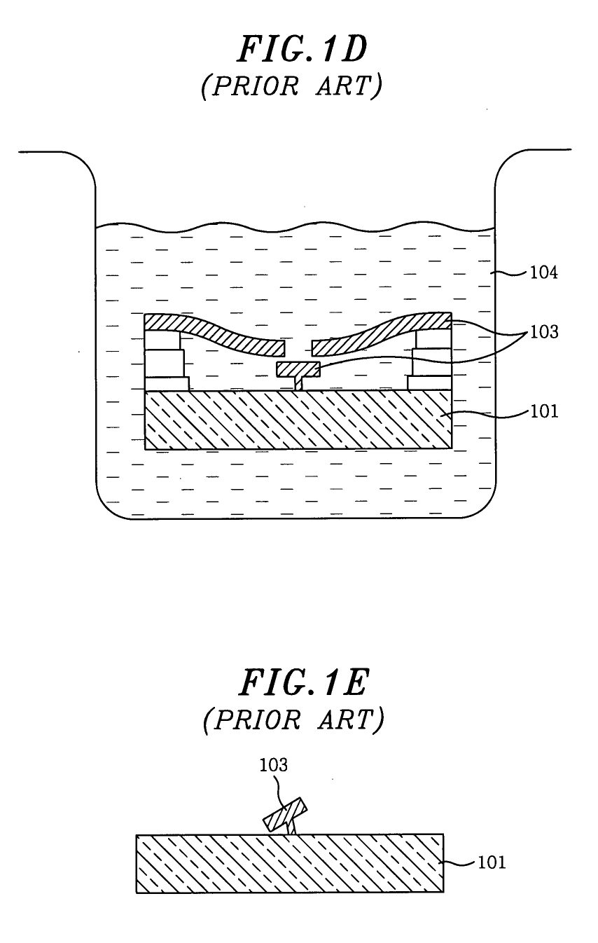

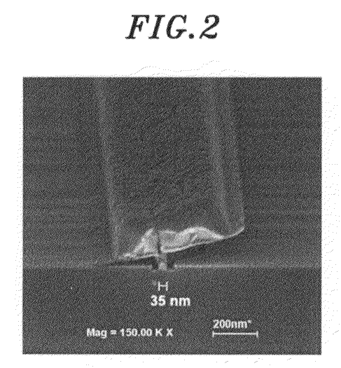

### DETAILED DESCRIPTION OF THE EMBODIMENTS

In the following description of the embodiments, reference is made to the accompanying drawings that form a part hereof, and in which is shown by way of illustration specific embodiments in which the invention may be practiced. It is to be understood that other embodiments may be utilized and structural changes may be made without departing from the scope of the present invention.

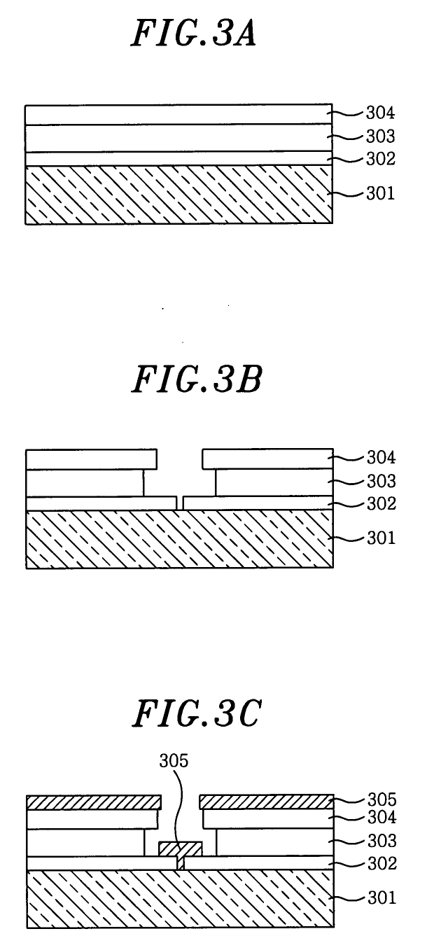

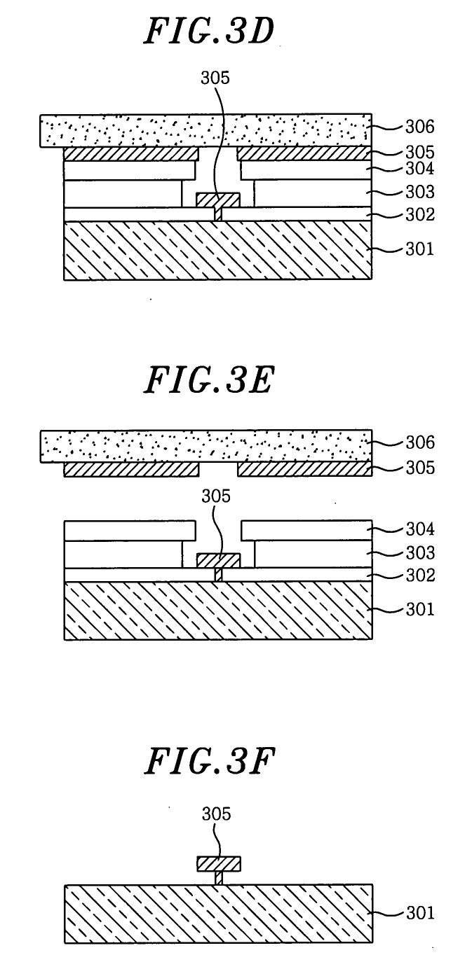

FIGS. 3A to 3F illustrate cross sectional views sequentially showing a process of forming a T-gate in accordance with the present invention. As shown in FIG. 3A, a plurality of resist films is sequentially laminated on a substrate 301. Herein, each laminated resist film has different sensitivity to the electron beam or reaction with a developing solution. For example, a bottom layer, i.e. a first resist film 302, is made of polymethyl methacrylate (PMMA) having relatively poor sensitivity to the electron beam, while a middle layer and a top layer, i.e. a second resist film 303 and a third resist film 304, are respectively made of polymethyl glutarimide (PMGI) and PMMA-methacrylic acid (PMMA-MAA) having relatively good sensitivity to the electron beam. Further, PMMA of the first resist film 302 is coated with a thickness of 50 nm to 150 nm, PMGI of the second resist film 303 is coated with a thickness of 450 nm to 500 nm, and PMMA-MAA of the third resist film 304 is coated with a thickness of 450 nm to 550 nm.

Next, by using electron lithography, all three layers of the resist films 302, 303, and 304 are exposed, developed and cleaned to thereby form a T-shaped pattern in the laminated resist films, as shown in FIG. 3B. Herein, the significant difference of the cross-sectional length between a gate head part and a gate foot part should be considered, therefore it is preferable to divide the electron beam exposure process into two steps, i.e. one for forming the gate head part and one for forming the gate foot part.

After that, as shown in FIG. 3C, a gate metal layer 305 is formed on the substrate 301 where the T-shaped pattern is also formed. Here, the gate metal layer 305 is typically formed with a layered structure of titanium/platinum/gold, however it can also be formed by any other material obvious to one skilled in the art, without departing from the scope of the present invention. Such gate metal is typically deposited by an electron beam deposition method or by a sputtering method.

Further, an adhesion member 306 is attached to the gate metal layer 305 formed on a top surface of the laminated resist films, as shown in FIG. 3D. Then, as shown in FIG. 3E, by detaching both the adhesion member 306 and the gate metal layer 305 attached thereto, the whole gate metal layer 305 formed on the resist films is removed. At this time, to stably separate the gate metal layer 305 from the top surface of the resist films, the adhesive strength between the adhesion member 306 and the gate metal layer 305 should be greater than that between the gate metal layer 305 and the top surface of the laminated resist films. Typically, an adhesive tape is used for the adhesion member, however any material capable of attaching itself to a metal surface may be used, or any other material obvious to one skilled in the art may be used without departing from the scope of the present invention.

Finally, as shown in FIG. 3F, a T-gate 305 is formed by putting the substrate 301 with the resist films remaining thereon into a solvent and removing the remaining resist films. In accordance with the present invention, the resist films are removed after the gate metal layer formed on the top surface of the laminated films is removed. Therefore, the possibility of having a physical impact caused by the movement of the remaining metal is eliminated, thereby making it possible to stably form the T-gate.

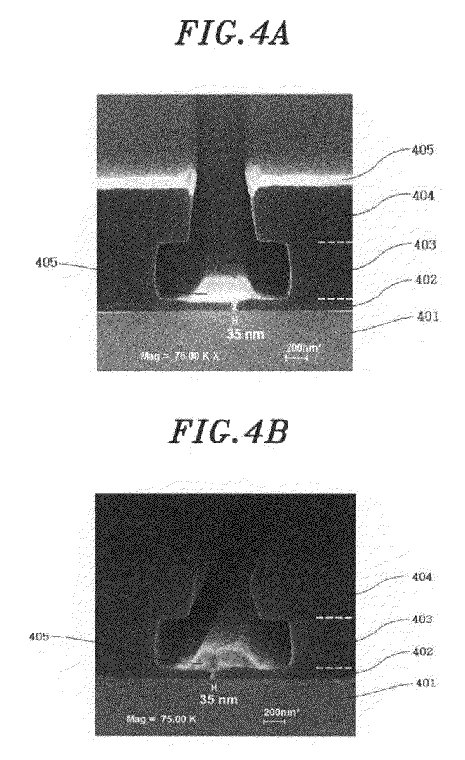

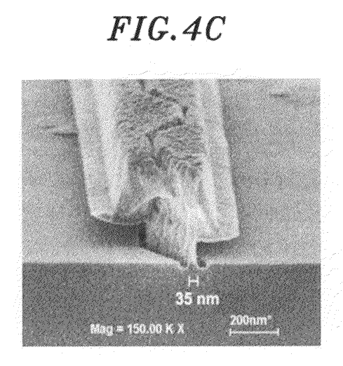

FIGS. 4A to 4C are photographs, which are captured by a scanning electron microscope, sequentially showing cross sections of a 35 nm T-gate actually formed by the above-mentioned method. In FIG. 4A, reference numeral 401 indicates a substrate, reference numerals 402, 403 and 404 respectively represent a first resist film, a second resist film and a third resist film, and reference numeral 405 indicates a gate metal layer formed by an electron beam. FIG. 4A illustrates a cross sectional view where the gate metal layer 405 is formed after a T-shaped pattern has been formed, while FIG. 4B shows a cross sectional view where the gate metal layer 405 formed on a top surface of resist films have been removed with an adhesive tape. Since there is no change in the top layer, i.e., the third resist film after the gate metal layer 405 is removed by the adhesive tape, it can be conjectured that there is no physical impact on the minutely patterned T-gate which is protected by the top layer of the resist films. FIG. 4C is a photograph, which is taken by an electron microscope, showing a cross section of the T-gate after the completion of the removal of the resist films and cleaning using a resist removal solution. As can be seen from FIG. 4C, the 35 nm T-gate is not tipped over to one side but is stably formed even after the metal removal process.

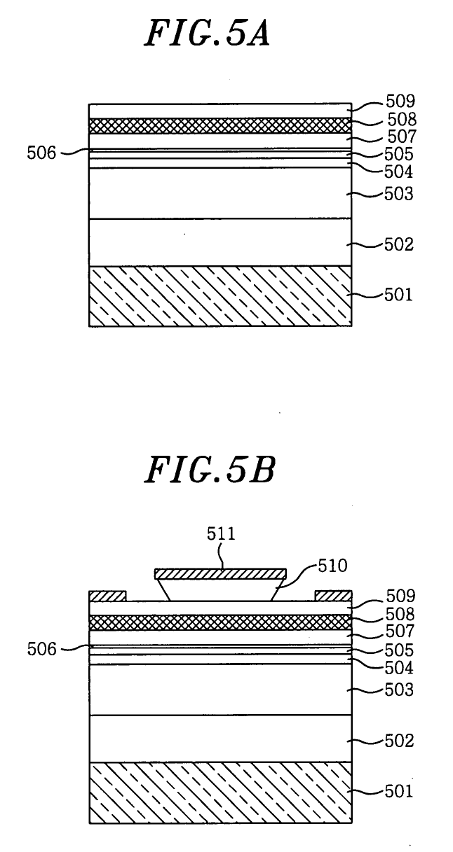

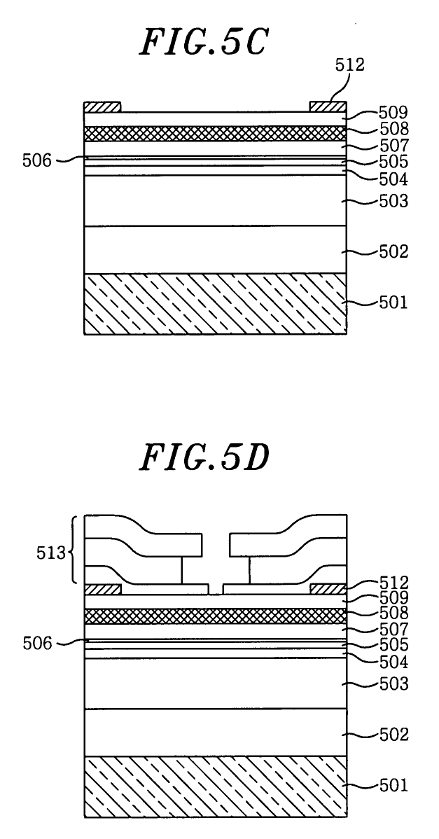

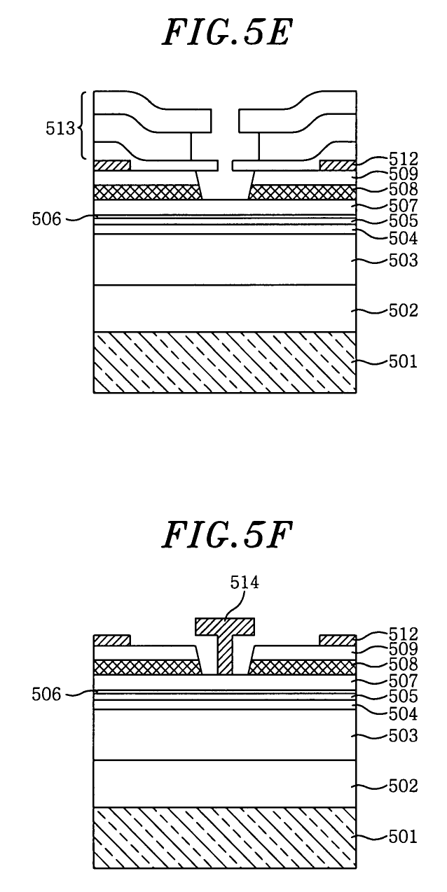

FIGS. 5A to 5F show cross sectional views sequentially showing a process of forming a metamorphic high electron mobility transistor (HEMT) by using the above-described T-gate forming method. First, as shown in FIG. 5A, a plurality of epitaxial layers, e.g., a metamorphic buffer layer 502, an undoped buffer layer 503, an undoped channel layer 504, an undoped spacer layer 505, a delta doping layer 506, a schottky barrier layer 507, an etching protective layer 508 and a cap layer 509, is sequentially formed on a compound semiconductor substrate 501. Here, the compound semiconductor substrate 501 includes a gallium arsenide (GaAs) substrate or an indium phosphide (InP) substrate.

For example, in a case where gallium arsenide (GaAs) is used as a substrate, the metamorphic buffer layer 502 is formed to have a thickness of 250 nm to 350 nm, the undoped buffer layer 503 is made of In_{0.52}Al_{0.48}As having a thickness of 250 nm to 350 nm, the channel layer is made of undoped In_{0.53}Ga_{0.47}As having a thickness of 100 nm to 200 nm, and the spacer layer 505 is made of undoped In_{0.52}Al_{0.48}As having a thickness of 5 nm to 10 nm. Further, the delta doping layer 506 is formed by doping an upper portion of the spacer layer 505 with a doping concentration of 6×10¹² cm⁻², and the schottky barrier layer 507 is formed of undoped In_{0.52}Al_{0.48}As having a thickness of 5 nm to 15 nm. The etching protective layer 508 is made of indium phosphide having a thickness of 5 nm to 10 nm, and the cap layer 509 is formed of In_{0.53}Ga_{0.47}As doped with a doping concentration of 1×10¹⁹ cm⁻³ and has a thickness of 15 nm to 25 nm. Here, the cap layer 509 is a highly doped layer that serves as an ohmic layer to reduce contact resistance with source and drain electrodes formed of an ohmic metal layer. Further, doping is performed using elements belonging to Group IV such as silicon. Due to the high etching selectivity of the etching protective layer 508 to the cap layer 509, the etching protective layer 508 can stop wet etching of the cap layer 509 or decrease an etching rate during a gate recess process which will be described later.

Subsequently, as shown in FIG. 5B, a resist film 510 is coated and patterned, and then an ohmic metal layer 511 is formed thereon. Ohmic metal layer 511 is deposited with titanium, platinum and gold with the thickness of 20 nm to 40 nm, 15 nm to 25 nm and 200 nm to 300 nm, respectively, by using an electron beam deposition method or a sputtering method.

After that, a source and a drain electrode 512 are formed by a lift-off method, as shown in FIG. 5C. At this time, a heat treatment process can be performed after the formation of the source and the drain electrode 512, otherwise a non-heat treatment process can be performed instead of the heat treatment process. For example, if titanium/platinum/gold serving as the ohmic metal layer 511 are deposited by the electron beam deposition method to form the source and the drain electrode 512, then a heat treatment process is not performed. In contrast, if gold-germanium alloy, nickel and gold are deposited, then a heat treatment process is performed to form an ohmic contact.

Further, as shown in FIG. 5D, resist films 513 are formed by the above-mentioned method and thereafter a T-shaped pattern is formed using electron beam lithography.

Next, as shown in FIG. 5E, the gate recess process for wet etching a specific portion of the cap layer 509 and the etching protective layer 508 by using the T-shaped pattern as a mask is carried out. At this time, due to a characteristic of the wet etching, etching occurs under the mask, which is referred to as undercutting, to thereby form a recessed portion shown in FIG. 5E. In order to more accurately control a thickness of the cap layer 509, the wet etching process is performed in two steps. First, the cap layer 509 is etched using an etching solution with a higher etching rate than that is required for the etching protective layer 508 whereby the etching of the cap layer 509 terminates when the solution reaches the etching protective layer 508. Then, the etching protective layer 508 is etched by using a second etching solution exclusive to the etching protective layer 508.

The gate recess process above can be simplified by using just one etching solution and varying the speed at which the etching solution etches the cap layer 509 and the etching protective layer 508. To be specific, the cap layer 509 is first etched by using an etching solution with a higher etching rate for the cap layer 509, and then the etching protective layer 508 is etched at a relatively lower speed compared to that of the cap layer 509, whereby it is possible to precisely control the ending point of the gate recess process.

Subsequently, after a gate metal layer is formed and the gate metal layer formed on the laminated resist films is removed by adhesion member, the remaining resist films are removed by a solvent to form a T-gate 514, whereby a metamorphic high electron mobility transistor shown in FIG. 5F is fabricated.

The metamorphic high electron mobility transistor having the above structure reduces parasitic resistance to improve the device characteristics. That is, the parasitic resistance of the device can be reduced by highly doping the etching protective layer 508 formed under the cap layer 509 to reduce contact resistance between the cap layer 509 serving as an ohmic layer and the etching protective layer 508. In a case where indium phosphide is used as the etching protective layer 508 for this purpose, the doping concentration can be controlled within a range of 1×10¹⁸ cm⁻³ to 5×10¹⁹ cm⁻³.

Hereinafter, experimental examples of the 35 nm T-gate metamorphic high electron mobility transistor manufactured by the above-described T-gate forming method will be described in detail along with test results of the device characteristics.

In this example, a gallium arsenide substrate is used as the compound semiconductor substrate. An epitaxial structure formed on the gallium arsenide substrate includes a 20 nm thick cap layer (In_{0.53}Ga_{0.47}As) doped with a doping concentration of 1×10¹⁹ cm⁻³, an 5 nm thick indium phosphide etching protective layer doped with a doping concentration of 5×10^{18 cm}⁻³, a 10 nm thick undoped schottky barrier layer (In_{0.52}Al_{0.48}As), a delta doping layer doped with a doping concentration of 6×10¹² cm⁻², a 4 nm thick undoped spacer layer (In_{0.52}Al_{0.48}As), a 150-nm thick undoped channel layer (In_{0.53}Ga_{0.47}As), a 300 nm thick undoped buffer layer (In_{0.52}Al_{0.48}As), and a 300 nm thick metamorphic buffer layer, which are all deposited sequentially from the top of the structure. After performing a mesa process (not shown) for isolating devices, an ohmic process for forming a source and a drain electrode is performed. The ohmic process is a non-heat treatment process, where titanium/platinum/gold are deposited to have the thickness of 30 nm/20 nm/250 nm by using an electron beam depositor and where the source and the drain electrode are formed by a lift-off method. The ohmic contact resistance measured after the ohmic process is 0.023 Ω·m, which confirms the good performance.

The process for forming the T-shaped gate employs a multilayer resist structure, where a bottom layer, i.e., a first resist film, is formed of PMMA having a thickness of 100 nm, a middle layer, i.e., a second resist film, is formed of PMGI having a thickness of 500 nm, and a top layer, i.e., a third resist film, is formed of PMMA-MAA having a thickness of 500 nm. After each resist film is coated, it is heated at 190° C. for 5 minutes and cooled for 10 minutes.

A gate patterning process is performed in two steps using the electron beam lithography. First, an electron beam is irradiated on an area of 0.5 μm×40 μm that is centered around a middle point between the source and the drain electrode at a beam intensity of 100 μC/cm², whereupon the third resist film of the top layer is developed using a third developing solution having a ratio of MIBK:IPA=1:3 for 90 seconds thereby removing the film. The second resist film is developed in a second developing solution (PMGI-101) for 5 minutes. When the patterning process of a gate head part of the T-gate is completed, lithography for forming a gate foot part is then carried out. To form a gate foot pattern in a zigzag shape, an electron beam is irradiated at a beam intensity of 4000 pC/cm and thereafter the first resist film is developed in a first developing solution having a ratio of MIBK:IPA=1:3 for 30 seconds.

A gate recess process is performed by using an etching solution that is based on citric acid with ammonium hydroxide with pH of 3.9. After the gate recess process, titanium/platinum/gold are deposited to have the thickness of 30 nm/20 nm/250 nm by using an electron beam depositor where the remaining metal is then removed by a metal removal method using an adhesive tape. After that, the remaining resist films are removed by a solvent to form the T-gate.

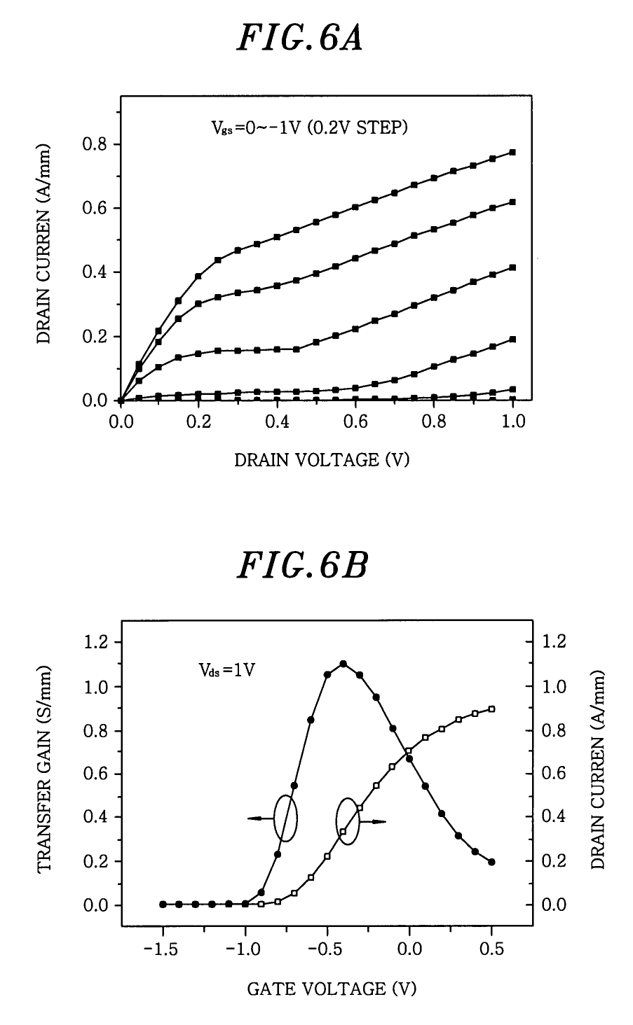

In order to test DC characteristics of the manufactured device, an Agilent 4156C semiconductor parameter analyzer and an ICS program are used to measure a direct current. FIG. 6A shows a graph illustrating DC characteristics of a 2 μm×40 μm device with a gate length of 35 nm, which exhibits good pinch-off characteristics at a gate voltage of −1 V. In FIG. 6B, a maximum drain current reads 896 mA/mm at a drain voltage of 1 V and a maximum transfer gain reads 1100 mS/mm at a gate voltage of −0.4 V, which are excellent DC characteristics. For the RF characteristics of the device, scattering coefficients of 1 GHz to 50 GHz are measured by performing a two-step de-embedding using a vector network analyzer 37397C manufactured by Anritsu Corporation.

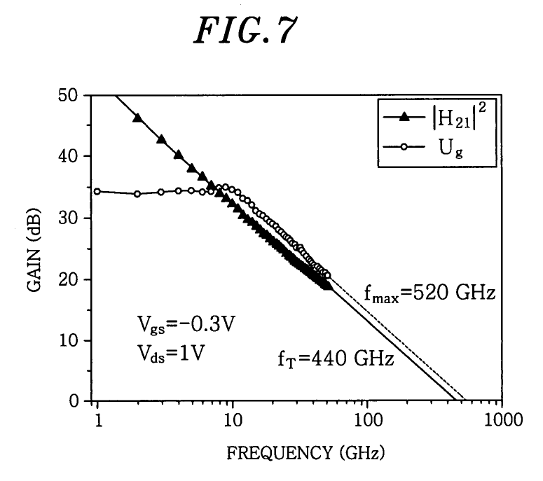

FIG. 7 is a graph showing ultra-high frequency characteristics of the 35 nm T-gate metamorphic high electron mobility transistor manufactured by the method of the present invention, where a maximum oscillating frequency fₘₐₓ of 520 GHz and a current gain cut-off frequency f_{T} of 440 GHz are derived from the measured scattering coefficients. Since the conventional best metamorphic high electron mobility transistor has a maximum oscillating frequency fₘₐₓ of 400 GHz and a current gain cut-off frequency of 440 GHZ (see, [K. Elgaid, et. al., IEEE Electron Device Lett. 26 (11), November 2005]), the present invention improves the best record of the maximum oscillating frequency of the conventional metamorphic high electron mobility transistor by more than 120 GHZ. Consequently, it is possible, with the present invention, to manufacture a metamorphic high electron mobility transistor capable of performing at a much higher ultra-high frequency operation than what is currently known in the arts.

While the invention has been shown and described with respect to the embodiments, it will be understood by those skilled in the art that various changes and modifications may be made without departing from the scope of the invention as defined in the following claims.

What is claimed is:

1. A method for forming a T-gate of a metamorphic high electron mobility transistor, the method comprising:
sequentially laminating a plurality of resist films on a substrate;
forming a T-shaped pattern in the laminated resist films using electron beam lithography;
forming a gate metal layer on the substrate where the T-shaped pattern has been formed;
attaching an adhesion member to the gate metal layer formed on a top surface of the laminated resist films and detaching the adhesion member to thereby remove the gate metal layer; and
removing the laminated resist films.

2. The method of claim 1, wherein the laminated resist films are formed by sequentially laminating polymethyl methacrylate (PMMA), polymethyl glutarimide (PMGI) and polymethyl methacrylate-methacrylic acid (PMMA-MAA) from the bottom up.

3. The method of claim 1, wherein the electron beam lithography includes the steps of:
patterning a gate head part of the T-gate; and
patterning a gate foot part of the T-gate.

4. The method of claim 1, wherein the gate metal layer is formed by sequentially depositing titanium, platinum and gold from the bottom up.

5. The method of claim 4, wherein titanium, platinum, and gold are deposited with thicknesses of 20 nm to 40 nm, 15 nm to 25 nm, and 200 nm to 300 nm, respectively.

6. The method of claim 1, wherein adhesive strength between the adhesion member and the gate metal layer is greater than that between the gate metal layer and the top surface of the laminated resist films.

7. The method of claim 1, wherein the adhesion member includes an adhesion tape.

8. A method for forming a metamorphic high electron mobility transistor, the method comprising:
sequentially laminating a metamorphic buffer layer, an undoped buffer layer, an undoped channel layer, an undoped spacer layer, a delta doping layer, a schottky barrier layer, an etching protective layer and a doped cap layer on a substrate;
forming an ohmic metal layer on the cap layer to thereby form a source and a drain electrode;
sequentially laminating a plurality of resist films on the cap layer on which the source and the drain electrode have been formed;
forming a T-shaped pattern in the laminated resist films using electron beam lithography;
performing a gate recess process for wet etching the cap layer and the etching protective layer using the T-shaped pattern as a mask;
forming a gate metal layer on the substrate after completing the gate recess process;
attaching an adhesion member to the gate metal layer formed on a top surface of the laminated resist films and detaching the adhesion member to thereby remove the gate metal layer; and
removing the laminated resist films.

9. The method of claim 8, wherein the substrate is selected from a group consisting of a gallium arsenide substrate and an indium phosphide substrate.

10. The method of claim 8, further comprising doping the etching protective layer.

11. The method of claim 10, wherein the etching protective layer is made of indium phosphide.

12. The method of claim 10, wherein doping concentration of the etching protection layer is within a range of 1×10¹⁸ cm⁻³ to 5×10¹⁹ cm⁻³.

13. The method of claim 8, wherein the ohmic metal layer is formed by sequentially depositing titanium, platinum and gold from the bottom up.

14. The method of claim 13, wherein titanium, platinum, and gold are deposited with thicknesses of 20 nm to 40 nm, 15 nm to 25 nm, and 200 nm to 300 nm, respectively.

15. The method of claim 8, wherein the ohmic metal layer is formed by sequentially depositing gold-germanium alloy, nickel and gold from the bottom up.

16. The method of claim 15, further comprising forming an ohmic contact between the ohmic metal layer and the cap layer by performing a heat treatment after forming the source and the drain electrode.

17. The method of claim 8, wherein the gate recess process includes:
etching the cap layer by using a first etching solution with a higher etching rate than that is required for the etching protective layer until the etching reaches the etching protective layer; and
etching the etching protective layer by using a second etching solution.

18. The method of claim 8, wherein, during the gate recess process, the cap layer and the etching protective layer are etched by using one etching solution with high etching rate and varying the speed at which the etching solution etches the cap layer and the etching protective layer.
